(19) United States
(12) Patent Application Publication
(10) Pub. No.: US 2023/0057312 A1
(43) Pub. Date: Feb. 23, 2023

(54) METALLIC NANO-TWINNED THIN FILM STRUCTURE AND METHOD FOR FORMING THE SAME

(71) Applicant: AG MATERIALS TECHNOLOGY CO., LTD., Hsinchu City (TW)

(72) Inventors: Tung-Han CHUANG, Hsinchu City (TW); Po-Ching WU, Hsinchu City (TW); Pei-Ing LEE, Hsinchu City (TW); Hsing-Hua TSAI, Hsinchu City (TW)

(21) Appl. No.: 17/488,171

(22) Filed: Sep. 28, 2021

(30) Foreign Application Priority Data
Aug. 20, 2021 (TW) 110130784

(51) Int. Cl. C23C 28/02

(52) U.S. Cl. CPC C23C 28/023; B82Y 30/00

(57) ABSTRACT

A metallic nano-twinned thin film structure and a method for forming the same are provided. The metallic nano-twinned thin film structure includes a substrate, an adhesive-lattice-buffer layer over the substrate, and a single-layer or multi-layer metallic nano-twinned thin film over the adhesive-lattice-buffer layer. The metallic nano-twinned thin film includes parallel-arranged twin boundaries (Σ3+Σ9). In a cross-sectional view of the metallic nano-twinned thin film, the parallel-arranged twin boundaries account for 30% to 90% of total twin boundaries. The parallel-arranged twin boundaries include 80% to 99% of crystal orientation [111]. The single-layer metallic nano-twinned thin film includes copper, gold, palladium or nickel. The multi-layer metallic nano-twinned thin films are respectively composed of silver, copper, gold, palladium or nickel.

### CROSS-REFERENCE TO RELATED APPLICATIONS

The present application claims priority of Taiwan Application No. 110130784, filed on Aug. 20, 2021, which is incorporated by reference herein in its entirety.

### BACKGROUND

### Technical Field

The present disclosure relates to a metallic thin film structure and a method for forming the same, and more particularly to a single-layer or multi-layer high-density metallic nano-twinned thin film structure and a method for forming the same.

### Description of the Related Art

Most conventional metal thin film structures are equi-axial grains with grain sizes of several microns or more. U.S. Patent Publication No. US20150275350A1 discloses a structure of silver or silver alloy nano-twinned thin film sputtered directly on a silicon substrate. The silver or silver alloy nano-twinned thin film has better tensile strength and conductivity than ordinary grains or nano equi-axial grains. However, the silver or silver alloy nano-twinned density is less than 30%.

Taiwan Patent No. I703226 discloses a structure of silver nano-twinned thin film sputtered on surface of a silicon chip, and its nano-twinned density can reach 75%. However, the sputtering method is extremely costly and the production rate is low. It is known that evaporation of thin films has the advantages of low cost and high production efficiency. Although Taiwan Patent No. I703226 also discloses a structure of silver nano-twinned thin film evaporated directly on surface of a silicon chip, its nano-twinned density is only 50%. Regardless of whether sputtering or direct evaporation method is used, Taiwan Patent No. I703226 fails to disclose the formation of high-density copper, gold, palladium or nickel nano-twinned thin film structures.

Taiwan Patent No. I419985 discloses the electroplating of silver, copper, gold or nickel thin film on a silicon oxide substrate. The metal thin film formed by the electroplating is then bombarded with ions to form mechanical twins. However, the distance between twin boundaries is between 8.3 nm and 45.6 nm. The distribution of crystal orientation is disorderly, and a large number of parallel-arranged nano twins cannot be formed. The nano-twinned density is also less than 50%.

Taiwan Patent No. I432613 discloses a method for electroplating a copper nano-twinned thin film. Taiwan Patent No. I521104 discloses a method for electroplating a copper seed layer and then electroplating nickel nano-twinned thin film. Taiwan Patent No. I507548 discloses a method for electroplating a gold nano-twinned thin film. These conventional techniques can form a large number of parallel-arranged nano-twinned thin films on a substrate. However, they all use a high-speed rotary electroplating method at a speed of 50 rpm or even 1,500 rpm. It is difficult to control the process and film quality. The resulting distance between twin boundaries is large, and the parallel-arranged twin boundaries include only 90% or even only 50% of the crystal orientation [111]. In addition, the electroplating waste produced by the electroplating process also has environmental concerns.

Obviously, there are still many shortcomings in the conventional metal nano-twinned thin film formation technology. There are still many challenges for the application of nano-twinned thin film in low-temperature die bonding of a semiconductor chip and ceramic substrate, and the application of low-temperature direct bonding of 3D-IC chip or wafer.

### SUMMARY

Some embodiments of the present disclosure provide a metallic nano-twinned thin film structure, including: a substrate; an adhesive-lattice-buffer layer over the substrate; and a single-layer or multi-layer metallic nano-twinned thin film over the adhesive-lattice-buffer layer. The metallic nano-twinned thin film includes parallel-arranged twin boundaries (Σ3+Σ9). The parallel-arranged twin boundaries account for 30% to 90% of the total twin boundaries in a cross-sectional view of the metallic nano-twinned thin film. The parallel-arranged twin boundaries include 80% to 99% of the crystal orientation [111]. The material of the metallic nano-twinned thin film includes silver, copper, gold, palladium or nickel. In the silver nano-twinned thin film, the parallel-arranged twin boundaries account for 50% to 95% of the total twin boundaries, and the parallel-arranged twin boundaries include 90% to 99% of the crystal orientation [111]. In the copper nano-twinned thin film, the parallel-arranged twin boundaries account for 45% to 90% of the total twin boundaries, and the parallel-arranged twin boundaries include 80% to 95% of the crystal orientation [111]. In the gold nano-twinned thin film, the parallel-arranged twin boundaries account for 40% to 80% of the total twin boundaries, and the parallel-arranged twin boundaries include 70% to 90% of the crystal orientation [111]. In the palladium nano-twinned thin film, the parallel-arranged twin boundaries account for 30% to 60% of the total twin boundaries, and the parallel-arranged twin boundaries include 60% to 90% of the crystal orientation [111]. In the nickel nano-twinned thin film, the parallel-arranged twin boundaries account for 30% to 60% of the total twin boundaries, and the parallel-arranged twin boundaries include 60% to 90% of the crystal orientation [111].

Some embodiments of the present disclosure provide a method for forming a metallic nano-twinned thin film structure, including: forming an adhesive-lattice-buffer layer on a substrate; and forming a single-layer or multi-layer metallic nano-twinned thin film on the adhesive-lattice-buffer layer. The metallic nano-twinned thin film includes parallel-arranged twin boundaries (Σ3+Σ9). The parallel-arranged twin boundaries account for 30% to 90% of the total twin boundaries in a cross-sectional view of the metallic nano-twinned thin film. The parallel-arranged twin boundaries include 80% to 99% of the crystal orientation [111]. The material of the metallic nano-twinned thin film includes silver, copper, gold, palladium or nickel. In the silver nano-twinned thin film, the parallel-arranged twin boundaries account for 50% to 95% of the total twin boundaries, and the parallel-arranged twin boundaries include 90% to 99% of the crystal orientation [111]. In the copper nano-twinned thin film, the parallel-arranged twin boundaries account for 45% to 90% of the total twin boundaries, and the parallel-arranged twin boundaries include 80% to 95% of the crystal orientation [111]. In the gold nano-twinned thin film, the parallel-arranged twin boundaries account for 40% to 80% of the total twin boundaries, and the parallel-arranged twin boundaries include 70% to 90% of the crystal orientation [111]. In the palladium nano-twinned thin film, the parallel-arranged twin boundaries account for 30% to 60% of the total twin boundaries, and the parallel-arranged twin boundaries include 60% to 90% of the crystal orientation [111]. In the nickel nano-twinned thin film, the parallel-arranged twin boundaries account for 30% to 60% of the total twin boundaries, and the parallel-arranged twin boundaries include 60% to 90% of the crystal orientation [111]. The high-density metallic nano-twinned thin film is formed by bombarding the surface of the evaporated film with an ion beam during the evaporation process.

### BRIEF DESCRIPTION OF THE DRAWINGS

Aspects of this disclosure are best understood from the following detailed description when read with the accompanying figures. It should be noted that, in accordance with common practice in the industry, various features are not drawn to scale. In fact, the dimensions of the various features may be arbitrarily increased or reduced for clarity of discussion.

FIG. 1 is a schematic diagram of using an ion beam to bombard the surface of the evaporated film during the evaporation process according to some embodiments of the present disclosure.

FIGS. 2A and 2B are cross-sectional views of a structure including an adhesive-lattice-buffer layer and a single-layer metallic nano-twinned thin film at different stages according to some embodiments of the present disclosure.

FIG. 3 is a cross-sectional view of a structure including an adhesive-lattice-buffer layer and a double-layer metallic nano-twinned thin film according to other embodiments of the present disclosure.

FIG. 4 is a cross-sectional view of a structure including an adhesive-lattice-buffer layer and a triple-layer metallic nano-twinned thin film according to other embodiments of the present disclosure.

FIGS. 5A to 5C are cross-sectional views of a structure including an adhesive-lattice-buffer layer, a diffusion-barrier-reaction layer and a single-layer metallic nano-twinned thin film at different stages according to other embodiments of the present disclosure.

FIG. 6 is a cross-sectional view of a structure including an adhesive-lattice-buffer layer, a diffusion-barrier-reaction layer and a double-layer metallic nano-twinned thin film according to other embodiments of the present disclosure.

FIG. 7 is a cross-sectional view of a structure including an adhesive-lattice-buffer layer, a diffusion-barrier-reaction layer and a triple-layer metallic nano-twinned thin film according to other embodiments of the present disclosure.

FIG. 8A is a focused ion beam (FIB) image of a cross-sectional view of an evaporated silver nano-twinned thin film on a single-crystalline silicon substrate without simultaneous ion-beam bombardment according to some comparative embodiments of the present disclosure.

FIG. 8B is an electron backscatter diffraction (EBSD) image of a cross-sectional view of an evaporated silver nano-twinned thin film on a single-crystalline silicon substrate without simultaneous ion-beam bombardment according to some comparative embodiments of the present disclosure.

FIG. 9 is an X-ray diffraction (XRD) pattern of a cross-sectional view of an evaporated silver nano-twinned thin film on a single-crystalline silicon substrate without simultaneous ion-beam bombardment according to some comparative embodiments of the present disclosure.

FIG. 10A is a FIB image of a cross-sectional view of an evaporated high-density silver nano-twinned thin film on a single-crystalline silicon substrate with ion-beam bombardment at the same time according to some embodiments of the present disclosure.

FIG. 10B is an EBSD image of a cross-sectional view of an evaporated high-density silver nano-twinned thin film on a single-crystalline silicon substrate with ion-beam bombardment at the same time according to some embodiments of the present disclosure.

FIG. 11 is an XRD pattern of a cross-sectional view of an evaporated high-density silver nano-twinned thin film on a single-crystalline silicon substrate with ion-beam bombardment at the same time according to some embodiments of the present disclosure.

FIG. 12A is a transmission electron microscope (TEM) image of a cross-sectional view of an evaporated high-density silver nano-twinned thin film on a single-crystalline silicon substrate with ion-beam bombardment at the same time according to some embodiments of the present disclosure.

FIG. 12B is a high-resolution transmission electron microscope (HRTEM) image of a cross-sectional view of an evaporated high-density silver nano-twinned thin film on a single-crystalline silicon substrate with ion-beam bombardment at the same time according to some embodiments of the present disclosure.

### DETAILED DESCRIPTION

The following disclosure provides many different embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Some variations of embodiments are described below. In different figures and illustrated embodiments, similar element symbols are used to indicate similar elements. It is appreciated that additional operations can be provided before, during, and/or after the stages described in these embodiments. Some of the stages that are described can be replaced or eliminated for different embodiments.

Furthermore, spatially relative terms, such as “beneath,” “below,” “lower,” “overlapped,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Furthermore, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The term “substantially” in the description, such as in “substantially peeling” will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%.

Embodiments of the present disclosure provide a metallic nano-twinned thin film structure, including a substrate, an adhesive-lattice-buffer layer over the substrate, and a single-layer or multi-layer silver, copper, gold, palladium or nickel nano-twinned thin film over the adhesive-lattice-buffer layer. The adhesive-lattice-buffer layer enhances the bonding force between the substrate and the metallic nano-twinned thin film. In addition, the adhesive-lattice-buffer layer may reduce the influence of the crystal orientation of the substrate on the metallic nano-twinned thin film. In a cross-sectional view, the formed metallic nano-twinned thin film includes parallel-arranged twin boundaries (Σ3+Σ9) which account for 30% to 90% of the total twin boundaries. The parallel-arranged twin boundaries include 80% to 99% of the crystal orientation [111]. The material of the metallic nano-twinned thin film includes silver, copper, gold, palladium or nickel. In the silver nano-twinned thin film, the parallel-arranged twin boundaries account for 50% to 95% of the total twin boundaries, and the parallel-arranged twin boundaries include 90% to 99% of the crystal orientation [111]. In the copper nano-twinned thin film, the parallel-arranged twin boundaries account for 45% to 90% of the total twin boundaries, and the parallel-arranged twin boundaries include 80% to 95% of the crystal orientation [111]. In the gold nano-twinned thin film, the parallel-arranged twin boundaries account for 40% to 80% of the total twin boundaries, and the parallel-arranged twin boundaries include 70% to 90% of the crystal orientation [111]. In the palladium nano-twinned thin film, the parallel-arranged twin boundaries account for 30% to 60% of the total twin boundaries, and the parallel-arranged twin boundaries include 60% to 90% of the crystal orientation [111]. In the nickel nano-twinned thin film, the parallel-arranged twin boundaries account for 30% to 60% of the total twin boundaries, and the parallel-arranged twin boundaries include 60% to 90% of the crystal orientation [111].

In general, the lower the stacking fault energy of the metal material, the easier it is to form a twin structure. The metal materials selected in the present disclosure all have very low stacking fault energy, such as silver (25 mJ/m²), copper (70 mJ/m²), gold (45 mJ/m²), palladium (130 mJ/m²) and nickel (225 mJ/m²), which are all conducive to the formation of the nano-twinned structure. In addition, the resistivity of the metal materials selected in the present disclosure is also low, such as silver (1.63 μΩ·cm), copper (1.69 μΩ·cm), gold (2.2 μΩ·cm), palladium (10.8 μΩ·cm) and nickel (6.90 μΩ·cm), and they can provide excellent conductivity for three-dimensional integrated circuit (3D-IC) wafer packaging.

In addition to the characteristics of metal itself, the characteristics of the twin structure, such as better resistance to oxidation, resistance to corrosion, electrical conductivity, thermal conductivity, and high temperature stability, etc., make the single-layer or multi-layer metallic nano-twinned thin film structure provided by the embodiments of the present disclosure more applicable in low-temperature die bonding of a semiconductor chip and ceramic substrate, and in low-temperature direct bonding of 3D-IC chip or wafer.

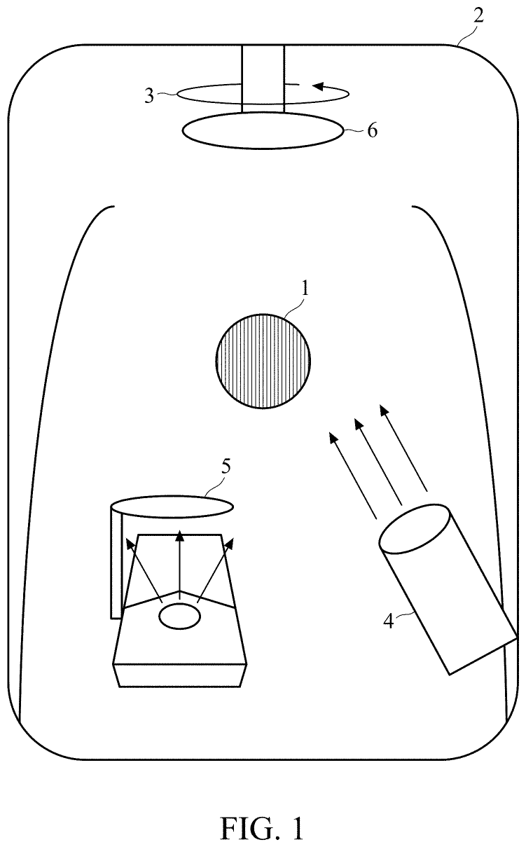

First of all, FIG. 1 illustrates a schematic diagram of using ion beams to bombard the surface of the evaporated film during the evaporation process of the present disclosure.

As shown in FIG. 1, the ion-beam bombardment-assisted evaporation process includes using a vacuum pump 1 to pre-pump the chamber 2 to a vacuum degree of less than 6×10⁻⁶ Torr, and 99.999% high-purity argon is introduced into the chamber 2. The flow rate is set to 4.5 sccm by the mass flow controller, until it is stable, and then the pressure of the chamber 2 is controlled to the required pressure of 1.5×10⁻⁴ Torr. The metal layer starts to prepare as follows. The rotation speed of the holder 3 is set to 10 rpm. The electron gun control handle is turned on to adjust the position of the electron beam and increase the power of the electron beam. The ion assist system 4 is turned on. The voltage and current are set. The shutter 5 is turned on, and the sample 6 is prepared by the evaporation.

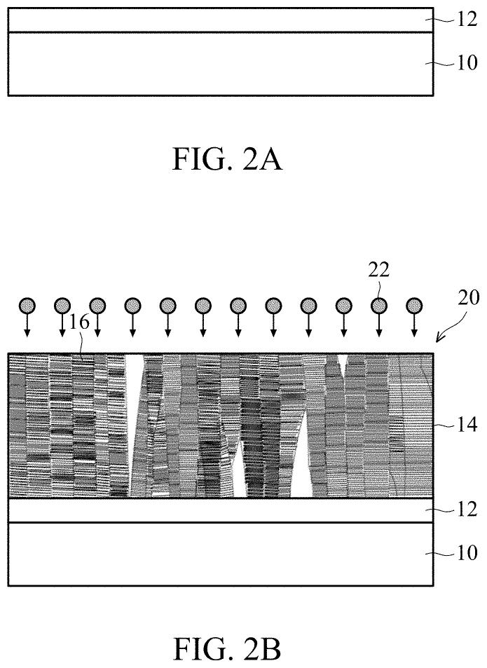

In accordance with some embodiments, FIGS. 2A and 2B illustrate cross-sectional views of a single-layer metallic nano-twinned thin film structure 20 at different stages.

Referring to FIG. 2A, an adhesive-lattice-buffer layer 12 is formed on a substrate 10. The adhesive-lattice-buffer layer 12 improves the bonding force between the substrate and the metallic nano-twinned thin film, and also has a lattice buffering effect. In some embodiments, the substrate 10 includes a silicon substrate, a silicon carbide substrate, a gallium arsenide substrate, a sapphire substrate or a glass substrate.

In some embodiments, the adhesive-lattice-buffer layer 12 may include titanium, chromium, aluminum or a combination thereof. In some embodiments, the thickness of the titanium-containing adhesive-lattice-buffer layer 12 may be 0.01 μm to 0.1 μm, such as 0.1 μm to 0.05 μm. In some embodiments, the thickness of the chromium-containing adhesive-lattice-buffer layer 12 may be 0.05 μm to 1 μm, such as 0.1 μm to 0.5 μm. In some embodiments, the thickness of the aluminum-containing adhesive-lattice-buffer layer 12 may be 0.1 μm to 1 μm, such as 0.1 μm to 0.5 μm. It should be understood that the thickness of the adhesive-lattice-buffer layer 12 may be appropriately adjusted according to practical applications, and is not intended to be limiting.

In accordance with other embodiments, as shown in FIG. 2A, the adhesive-lattice-buffer layer 12 may be formed on the substrate 10 by sputtering or evaporation.

In some embodiments, the sputtering adopts single-gun sputtering or multi-gun co-sputtering. In the sputtering process, the power source may use, for example, DC, DC plus, RF, or high-power impulse magnetron sputtering (HIPIMS). The sputtering power of the adhesive-lattice-buffer layer 12 may be, for example, about 100 W to about 500 W. The temperature of the sputtering process is room temperature, but the temperature will rise by about 50° C. to about 200° C. during the sputtering process. The background pressure of the sputtering process is 1×10⁻⁵ Torr. The working pressure may be, for example, about 1×10⁻³ Torr to about 1×10⁻² Torr. The flow rate of argon is about 10 sccm to about 20 sccm. The rotation speed of the stage may be, for example, about 5 rpm to about 20 rpm. The bias voltage applied to the substrate during the sputtering process is about −100V to about −200V. The deposition rate of the adhesive-lattice-buffer layer 12 may be, for example, about 0.5 nm/s to about 3 nm/s. It should be understood that the parameters of the sputtering process described above may be appropriately adjusted according to practical applications, and are not intended to be limiting.

In some embodiments, the background pressure of the evaporation process is 1×10⁻⁵ Torr. The working pressure may be, for example, about 1×10⁻⁴ Torr to about 5×10⁻⁴ Torr. The flow rate of argon is about 2 sccm to about 10 sccm. The rotation speed of the stage may be, for example, about 5 rpm to about 20 rpm. The deposition rate of the adhesive-lattice-buffer layer 12 may be, for example, about 1 nm/s to about 5.0 nm/s. It should be understood that the parameters of the evaporation process described above may be appropriately adjusted according to practical applications, and are not intended to be limiting.

Referring to FIG. 2B, a single-layer metallic nano-twinned thin film 14 is formed on the adhesive-lattice-buffer layer 12 using the disclosed ion-beam bombardment-assisted evaporation method. The material of the metallic nano-twinned thin film includes silver, copper, gold, palladium or nickel. In some embodiments, the metallic nano-twinned thin film 14 includes nano-scale parallel-arranged twin boundaries (Σ3+Σ9), and the distance between the nano-scale parallel-arranged twin boundaries may be, for example, 1 nm to 100 nm. In a cross-sectional view of the silver nano-twinned thin film 14, the parallel-arranged twin boundaries account for 50% to 95% of the total twin boundaries, and the parallel-arranged twin boundaries include 90% to 99% of the crystal orientation [111]. The material of the metallic nano-twinned thin film disclosed in the present disclosure further includes copper, gold, palladium or nickel. In the copper nano-twinned thin film, the parallel-arranged twin boundaries account for 45% to 90% of the total twin boundaries, and the parallel-arranged twin boundaries include 80% to 95% of the crystal orientation [111]. In the gold nano-twinned thin film, the parallel-arranged twin boundaries account for 40% to 80% of the total twin boundaries, and the parallel-arranged twin boundaries include 70% to 90% of the crystal orientation [111]. In the palladium nano-twinned thin film, the parallel-arranged twin boundaries account for 30% to 60% of the total twin boundaries, and the parallel-arranged twin boundaries include 60% to 90% of the crystal orientation [111]. In the nickel nano-twinned thin film, the parallel-arranged twin boundaries account for 30% to 60% of the total twin boundaries, and the parallel-arranged twin boundaries include 60% to 90% of the crystal orientation [111].

In accordance with some embodiments, as shown in FIG. 2B, the metallic nano-twinned thin film 14 includes parallel-stacked metallic nano-twinned pillars 16. In some embodiments, the thickness of the metallic nano-twinned thin film 14 may be 0.1 μm to 100 μm, such as 0.5 μm to 20 μm. In some embodiments, the diameters of the metallic nano-twinned pillars 16 may be 0.01 μm to 100 μm, such as 0.3 μm to 0.5 μm. It should be understood that the thickness of the metallic nano-twinned thin film 14 and the diameters of the metallic nano-twinned pillars 16 may be appropriately adjusted according to practical applications, and are not intended to be limiting.

In accordance with other embodiments, as shown in FIG. 2B, a single-layer metallic nano-twinned thin film 14 is formed on the adhesive-lattice-buffer layer 12 using the ion-beam bombardment-assisted evaporation method 22. In some embodiments, the vacuum degree of the evaporation process may be, for example, 10⁻² Torr to 10⁻⁶ Torr, or 10⁻³ Torr to 10⁻⁶ Torr. The scanning frequency of the evaporation electron beam may be, for example, about 2 Hz. The rotation speed of the evaporation stage may be 1 rpm to 20 rpm, or 5 rpm to 10 rpm. The ion-beam bombardment may use an argon ion beam or an oxygen ion beam. The flow rate of the ion beam may be 1 sccm to 20 sccm, or 3 sccm to 10 sccm. The voltage of the ion gun may be 10V to 5 KV, or 50V to 150V, or 60V to 100V. The current of the ion gun may be 0.2 A to 20 A. The evaporation rate of the metallic nano-twinned thin film 14 may be, for example, 0.1 nm/s to 100 nm/s, or 0.1 nm/s to 10 nm/s, or 0.2 nm/s to 1 nm/s. It should be understood that the parameters of the evaporation process described above may be appropriately adjusted according to practical applications, and are not intended to be limiting.

In the prior art, the silver nano-twinned thin films are directly sputtered on the substrates with (111) and (110) crystal orientations (D. Bufford, H. Wang, and X. Zhang, High Strength Epitaxial Nano-Twinned Ag Films, Acta Materialia, 59, 2011, pp. 93-101.). However, the literature of Bufford et al. pointed out that the silver nano-twinned thin films with high twin density can be sputtered on the (111) substrate only, and the nano-twinned density is less than 50%. Especially, on the (110) substrate, the deposited silver nano-twinned thin film has a very low twin density. Moreover, the twin boundaries distort from the direction of growth of the thin film by up to 60°.

Taiwan Patent No. I703226 discloses sputtering a silver nano-twinned thin film structure on surface of a silicon chip, and its nano-twinned density can reach 75%. However, the sputtering method is extremely costly and the production rate is low. It is known that evaporation of thin films has the advantages of low cost and high production efficiency. Although Taiwan Patent No. I703226 also discloses directly evaporating a silver nano-twinned thin film structure on surface of a silicon chip, its nano-twinned density is only 50%. The metallic thin film undergoes solidification reaction and cooling volume shrinkage phenomenon during the evaporation process. The shrinkage rate of the metal is about 15 ppm/K to 20 ppm/K, which is higher than that of silicon chips (3 ppm/K). After being solidified and then cooled to room temperature, the metallic thin film will form tensile stress. The ion-beam bombardment can apply compressive stress to the metallic thin film and relax the tensile stress of the metallic thin film (i.e. stress relaxation). The stress relaxation can trigger the formation of nano twins. Therefore, the present disclosure utilizes the evaporation process with simultaneous ion-beam bombardment on the surface of the thin film, and successfully makes the evaporated silver thin film has a high density of nano twins. The use of the ion-beam bombardment-assisted evaporation method also proves that high-density nano-twinned thin film structures of copper, gold, palladium and nickel can be obtained.

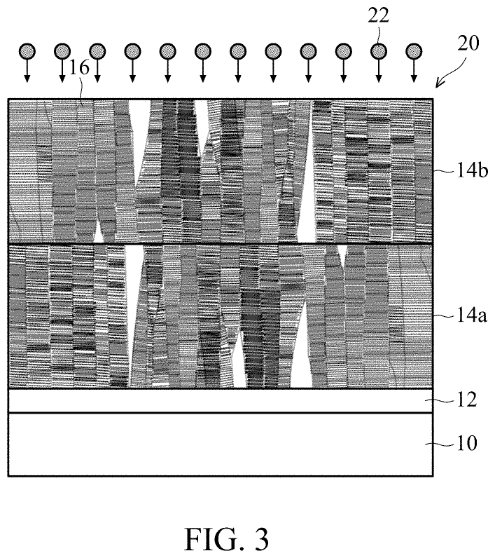

FIG. 3 is based on other embodiments. The present disclosure can also use the ion-beam bombardment-assisted evaporation method 22 to form a double-layer metallic nano twinned thin film (14a and 14b) on the substrate 10.

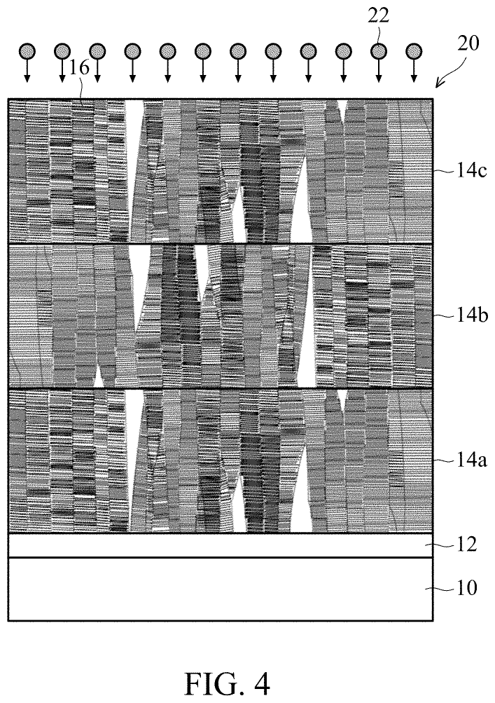

FIG. 4 is based on other embodiments. The present disclosure can also use the ion-beam bombardment-assisted evaporation method 22 to form a triple-layer metallic nano twinned thin film (14a, 14b and 14c) on the substrate 10.

In accordance with other embodiments, the present disclosure can also use the ion-beam bombardment-assisted evaporation method 22 to form four or more metallic nano twinned thin films (not shown) on the substrate 10.

In accordance with some embodiments of the present disclosure, in the application of the semiconductor packaging process, the metallic nano-twinned thin film 14 may have solid-liquid interfacial reactions with other packaging materials, for example, in solder reflow bonding. In order to improve the bonding force between the adhesive-lattice-buffer layer 12 and the metallic nano-twinned thin film 14 and avoid metal of each layer diffusing into each other, a diffusion-barrier-reaction layer 18 may be formed between the adhesive-lattice-buffer layer 12 and the metallic nano-twinned thin film 14. The diffusion-barrier-reaction layer is formed by evaporation, sputtering or electroplating.

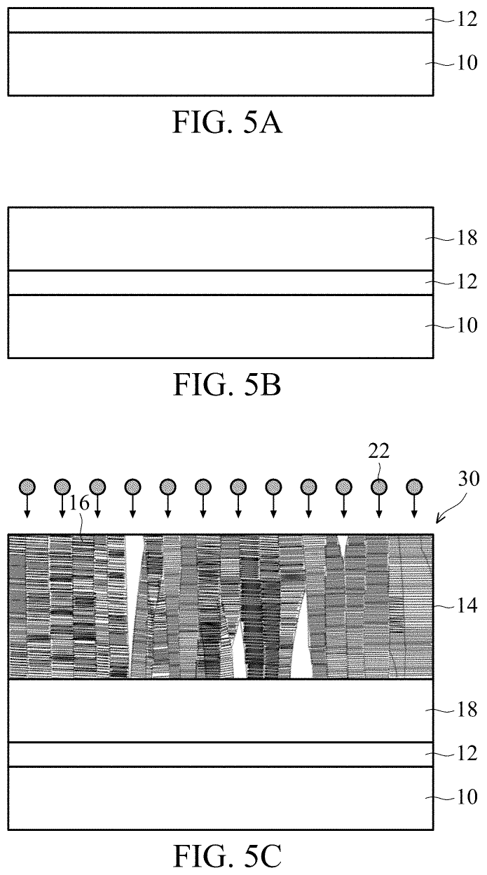

In accordance with other embodiments, FIGS. 5A to 5C are cross-sectional views of a metallic nano-twinned thin film structure 30 at different stages. Compared to the embodiments shown in FIGS. 2A and 2B, the diffusion-barrier-reaction layer 18 is additionally formed between the adhesive-lattice-buffer layer 12 and the metallic nano-twinned thin film 14.

Referring to FIG. 5A, in some embodiments, for the material of the substrate 10, reference may be made to the embodiment shown in FIG. 2A. Thus, it is not repeated again.

In some embodiments, for the material of the adhesive-lattice-buffer layer 12, the thickness of the titanium-containing adhesive-lattice-buffer layer 12, the thickness of the chromium-containing adhesive-lattice-buffer layer 12 and the thickness of the aluminum-containing adhesive-lattice-buffer layer 12, reference may be made to the embodiment shown in FIG. 2A. Thus, it is not repeated again. It should be understood that the thickness of the adhesive-lattice-buffer layer 12 may be appropriately adjusted according to practical applications, and is not limited to the embodiment shown in FIG. 2A.

In accordance with some embodiments, as shown in FIG. 5A, the adhesive-lattice-buffer layer 12 may be formed on the substrate 10 by sputtering or evaporation.

In some embodiments, the sputtering adopts single-gun sputtering or multi-gun co-sputtering. In the sputtering process, the power source may use, for example, DC, DC plus, RF, or high-power impulse magnetron sputtering (HIPIMS). The sputtering power of the adhesive-lattice-buffer layer 12 may be, for example, about 100 W to about 500 W. The temperature of the sputtering process is room temperature, but the temperature will rise by about 50° C. to about 200° C. during the sputtering process. The background pressure of the sputtering process is 1×10⁻⁵ Torr. The working pressure may be, for example, about 1×10⁻³ Torr to about 1×10⁻² Torr. The flow rate of argon is about 10 sccm to about 20 sccm. The rotation speed of the stage may be, for example, about 5 rpm to about 20 rpm. The bias voltage applied to the substrate during the sputtering process is about −100V to about −200V. The deposition rate of the adhesive-lattice-buffer layer 12 may be, for example, about 0.5 nm/s to about 3 nm/s. It should be understood that the parameters of the sputtering process described above may be appropriately adjusted according to practical applications, and are not intended to be limiting.

In some embodiments, the background pressure of the evaporation process is 1×10⁻⁵ Torr. The working pressure may be, for example, about 1×10⁻⁴ Torr to about 5×10⁻⁴ Torr. The flow rate of argon is about 2 sccm to about 10 sccm. The rotation speed of the stage may be, for example, about 5 rpm to about 20 rpm. The deposition rate of the adhesive-lattice-buffer layer 12 may be, for example, about 1 nm/s to about 5.0 nm/s. It should be understood that the parameters of the evaporation process described above may be appropriately adjusted according to practical applications, and are not intended to be limiting.

Referring to FIG. 5B, the diffusion-barrier-reaction layer 18 is formed on the adhesive-lattice-buffer layer 12. In some embodiments, the diffusion-barrier-reaction layer 18 may include nickel, copper or a combination thereof In some embodiments, the thickness of the nickel-containing diffusion-barrier-reaction layer 18 may be 0.1 μm to 100 μm, such as 0.5 μm to 20 μm. In some embodiments, the thickness of the copper-containing diffusion-barrier-reaction layer 18 may be 0.1 μm to 300 μm, such as 1.0 μm to 100 μm. It should be understood that the thickness of the diffusion-barrier-reaction layer 18 may be appropriately adjusted according to practical applications, and is not intended to be limiting.

In accordance with some embodiments, as shown in FIG. 5B, the diffusion-barrier-reaction layer 18 may be formed on the adhesive-lattice-buffer layer 12 by sputtering, evaporation or electroplating.

In some embodiments, the sputtering adopts single-gun sputtering or multi-gun co-sputtering. In the sputtering process, the power source may use, for example, DC, DC plus, RF, or high-power impulse magnetron sputtering (HIPIMS). The sputtering power of the diffusion-barrier-reaction layer 18 may be, for example, about 100 W to about 500 W. The temperature of the sputtering process is room temperature, but the temperature will rise by about 50° C. to about 200° C. during the sputtering process. The background pressure of the sputtering process is 1×10⁻⁵ Torr. The working pressure may be, for example, about 1×10⁻³ Torr to about 1×10⁻² Torr. The flow rate of argon is about 10 sccm to about 20 sccm. The rotation speed of the stage may be, for example, about 5 rpm to about 20 rpm. The bias voltage applied to the substrate during the sputtering process is about −100V to about −200V. The deposition rate of the diffusion-barrier-reaction layer 18 may be, for example, about 0.5 nm/s to about 3 nm/s. It should be understood that the parameters of the sputtering process described above may be appropriately adjusted according to practical applications, and are not intended to be limiting.

In some embodiments, the background pressure of the evaporation process is 1×10⁻⁵ Torr. The working pressure may be, for example, about 1×10⁻⁴ Torr to about 5×10⁻⁴ Torr. The flow rate of argon is about 2 sccm to about 10 sccm. The rotation speed of the stage may be, for example, about 5 rpm to about 20 rpm. The deposition rate of the diffusion-barrier-reaction layer 18 may be, for example, about 1 nm/s to about 5.0 nm/s. It should be understood that the parameters of the evaporation process described above may be appropriately adjusted according to practical applications, and are not intended to be limiting.

In some embodiments, the diffusion-barrier-reaction layer 18 can prevent the metal of the subsequently formed metal layer from diffusing toward the substrate 10, or prevent the metal of the adhesive-lattice-buffer layer 12 from diffusing toward the subsequently formed metal layer.

Referring to FIG. 5C, the single-layer metallic nano-twinned thin film 14 is formed on the diffusion-barrier-reaction layer 18 using the disclosed ion-beam bombardment-assisted evaporation method 22. The material of the metallic nano-twinned thin film includes silver, copper, gold, palladium or nickel. In some embodiments, for the twin structure of the metallic nano-twinned thin film 14, reference may be made to the embodiment shown in FIG. 2B. Thus, it is not repeated again.

In accordance with some embodiments, as shown in FIG. 5C, the metallic nano-twinned thin film 14 formed by the ion-beam bombardment-assisted evaporation includes parallel-stacked metallic nano-twinned pillars 16. In some embodiments, for the thickness of the metallic nano-twinned thin film 14 and the diameters of the metallic nano-twinned pillars 16, reference may be made to the embodiment shown in FIG. 2B. Thus, it is not repeated again. It should be understood that the thickness of the metallic nano-twinned thin film 14 and the diameters of the metallic nano-twinned pillars 16 may be appropriately adjusted according to practical applications, and are not limited to the embodiment shown in FIG. 2B.

In accordance with other embodiments, as shown in FIG. 5C, the single-layer metallic nano-twinned thin film 14 is formed on the diffusion-barrier-reaction layer 18 using the ion-beam bombardment-assisted evaporation method 22. In some embodiments, the vacuum degree of the evaporation process may be, for example, 10⁻² Torr to 10⁻⁶ Torr, or 10⁻³ Torr to 10⁻⁶ Torr. The scanning frequency of the evaporation electron beam may be, for example, about 2 Hz. The rotation speed of the evaporation stage may be 1 rpm to 20 rpm, or 5 rpm to 10 rpm. The ion-beam bombardment may use an argon ion beam or an oxygen ion beam. The flow rate of the ion beam may be 1 sccm to 20 sccm, or 3 sccm to 10 sccm. The voltage of the ion gun may be 10V to 5 KV, or 50V to 150V, or 60V to 100V. The current of the ion gun may be 0.2 A to 20 A. The evaporation rate of the metallic nano-twinned thin film 14 may be, for example, 0.1 nm/s to 100 nm/s, or 0.1 nm/s to 10 nm/s, or 0.2 nm/s to 1 nm/s. It should be understood that the parameters of the evaporation process described above may be appropriately adjusted according to practical applications, and are not intended to be limiting.

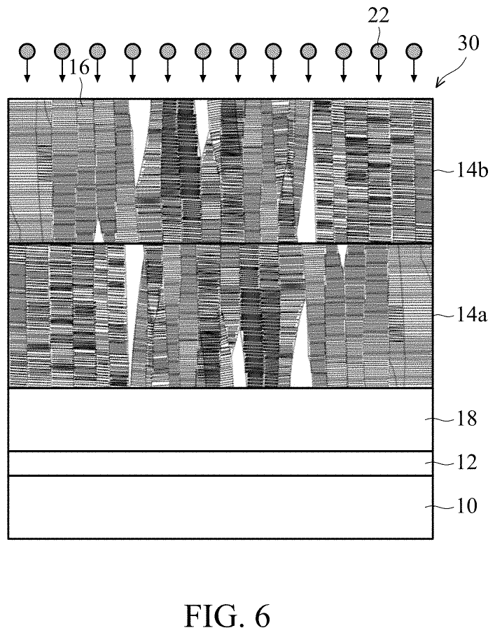

FIG. 6 is based on other embodiments. The present disclosure can also use the ion-beam bombardment-assisted evaporation method 22 to form a double-layer metallic nano twinned thin film (14a and 14b) on the substrate 10.

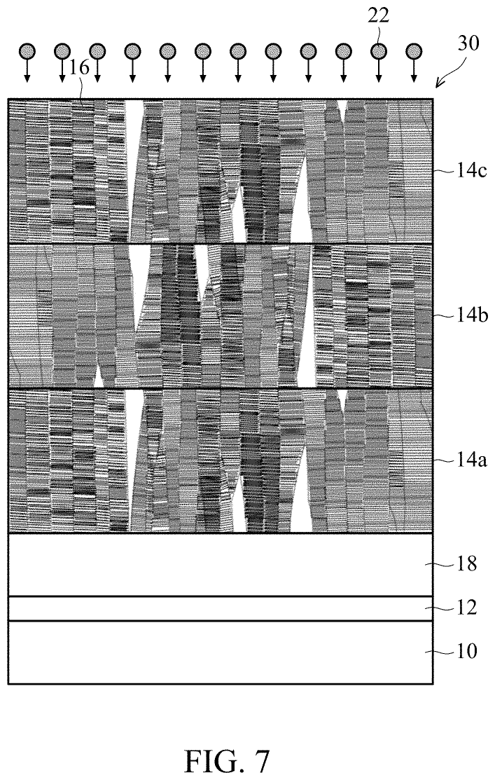

FIG. 7 is based on other embodiments. The present disclosure can also use the ion-beam bombardment-assisted evaporation method 22 to form a triple-layer metallic nano twinned thin film (14a, 14b and 14c) on the substrate 10.

In accordance with other embodiments, the present disclosure can also use the ion-beam bombardment-assisted evaporation method 22 to form four or more metallic nano twinned thin films (not shown) on the substrate 10.

The following describes the formation and detection results of some embodiments and comparative embodiments of the present disclosure in detail.

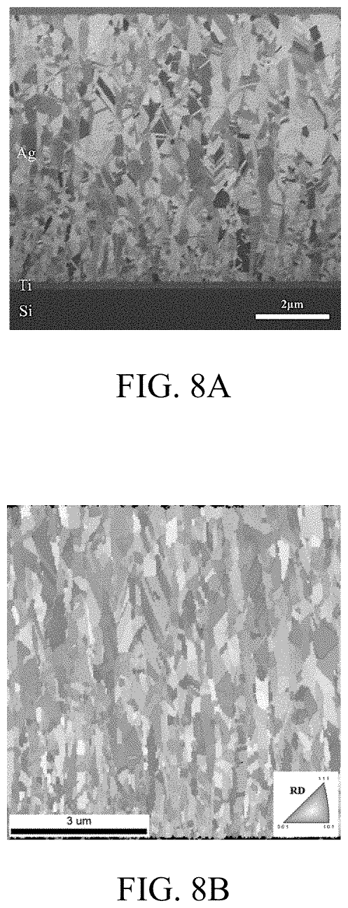

FIGS. 8A and 8B are based on some comparative embodiments. The focused ion beam (FIB) image (FIG. 8A) and the electron backscatter diffraction (EBSD) image (FIG. 8B) of the cross-sectional view of the evaporated silver nano-twinned thin film on the (100) single-crystalline silicon substrate without simultaneous ion-beam bombardment are shown. The evaporation parameters of the comparative embodiment are described as follows.

Evaporation rate: titanium: 0.1 nm/s, silver: 1.8 nm/s; Thickness: 7 μm; Background pressure: less than 6×10⁻⁶ Torr; Flow rate of argon: 4.5 sccm; Working pressure of argon: 1.5×10⁻⁴ Torr; Rotation speed of stage: 10 rpm; and Process temperature: normal temperature.

The results show that the cross-sectional view contains nano-scale parallel-arranged twin boundaries (Σ3+Σ9), but they only account for about 24% of the total twin boundaries. Obviously, the evaporation without applying ion-beam bombardment can only form low-density nano-twinned thin films.

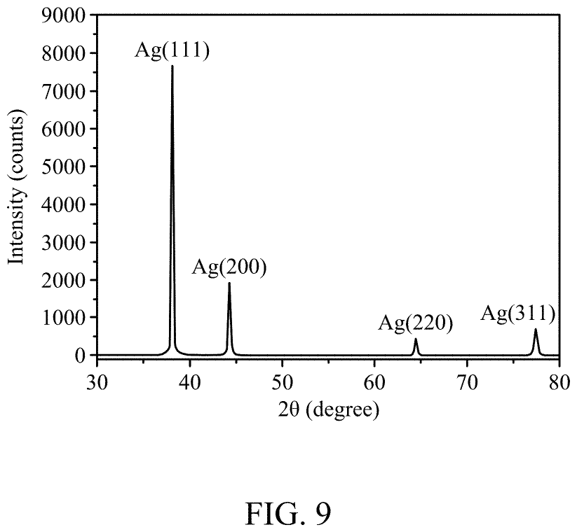

FIG. 9 is based on some comparative embodiments. The X-ray diffraction (XRD) pattern of the cross-sectional view of the evaporated silver nano-twinned thin film on the (100) single-crystalline silicon substrate without simultaneous ion-beam bombardment is shown. The results show that the XRD pattern still has obvious crystal orientations of (200), (220) and (311). Obviously, in the nano-twinned thin film formed by the evaporation without applying ion-beam bombardment, only a part of the parallel-arranged twin boundaries have preferred crystal orientation [111].

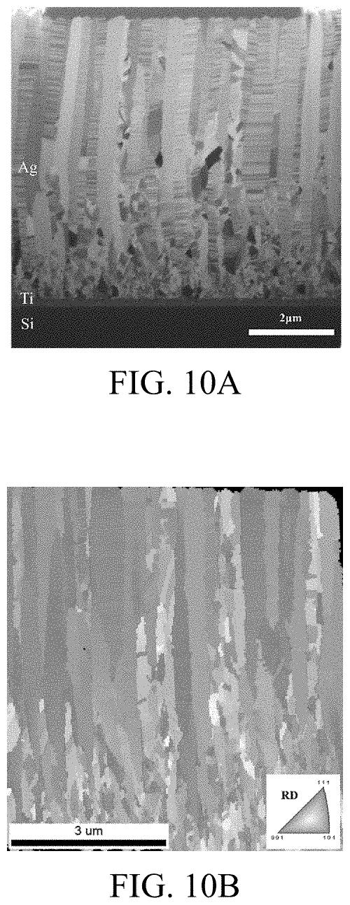

FIGS. 10A and 10B are based on some embodiments. The focused ion beam (FIB) image (FIG. 10A) and the electron backscatter diffraction (EBSD) image (FIG. 10B) of the cross-sectional view of the evaporated high-density silver nano-twinned thin film on the (100) single-crystalline silicon substrate with simultaneous ion-beam bombardment are shown. The evaporation parameters and ion gun parameters of the embodiment are described as follows.

Evaporation rate: titanium: 0.1 nm/s, silver: 1.8 nm/s; Thickness: 7 μm; Background pressure: less than 6×10⁻⁶ Torr; Flow rate of argon: 4.5 sccm; Working pressure of argon: 1.5×10⁻⁴ Torr; Rotation speed of stage: 10 rpm; Process temperature: normal temperature; Voltage of ion gun: 100V; and Current of ion gun: 0.4 A.

The results show that the cross-sectional view contains the nano-scale parallel-arranged twin boundaries Σ3 and Σ9 which accounts for 66% and 2% of the total twin boundaries, respectively. In total, the nano-scale parallel-arranged twin boundaries (Σ3+Σ9) account for 68% of the total twin boundaries. Obviously, the density of the nano-scale parallel-arranged twin boundaries of the nano-twinned thin film formed by evaporation with simultaneous ion-beam bombardment is much higher than that of the nano-twinned thin film formed by the evaporation without ion-beam bombardment in FIGS. 8A and 8B.

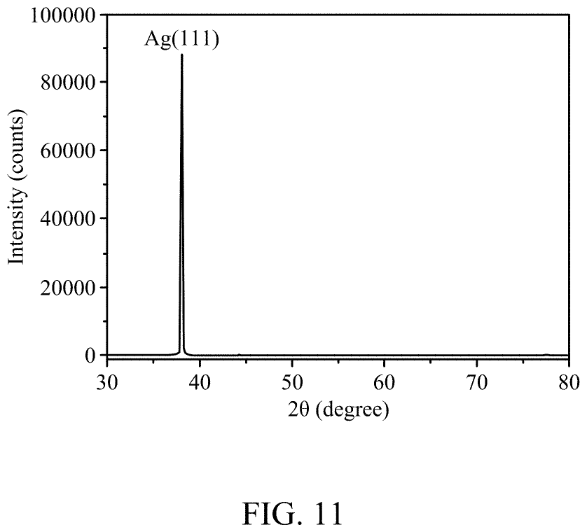

FIG. 11 is based on some embodiments. The X-ray diffraction (XRD) pattern of the cross-sectional view of the evaporated high-density silver nano-twinned thin film on the (100) single-crystalline silicon substrate with simultaneous ion-beam bombardment is shown. The results show that the parallel-arranged twin boundaries of the evaporated high-density silver nano-twinned thin film with simultaneous ion-beam bombardment have close to 100% of the preferred crystal orientation [111]. Obviously, the preferred crystal orientation [111] in the XRD pattern of the cross-sectional view of the nano-twinned thin film formed by evaporation with simultaneous ion-beam bombardment is much higher than that of the nano-twinned thin film formed by the evaporation without ion-beam bombardment in FIG. 9.

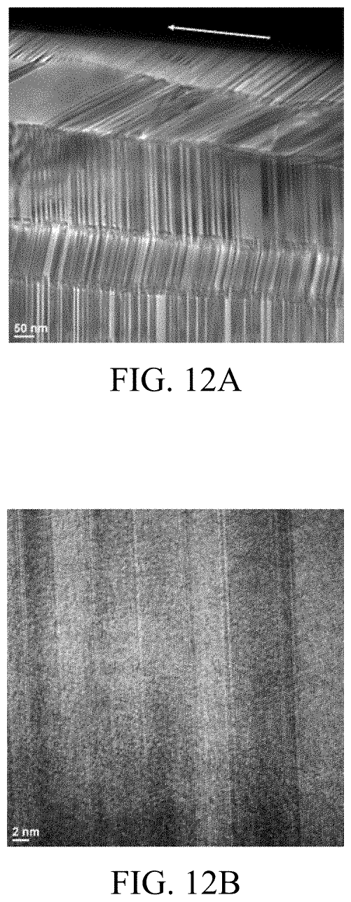

FIGS. 12A and 12B are based on some embodiments. The transmission electron microscope (TEM) image (FIG. 12A) and the high-resolution transmission electron microscope (HRTEM) image (FIG. 12B) of the cross-sectional view of the evaporated high-density silver nano-twinned thin film on the (100) single-crystalline silicon substrate with simultaneous ion-beam bombardment are shown. The results show that the distance between the parallel-arranged twin boundaries of the evaporated high-density silver nano-twinned thin film with simultaneous ion-beam bombardment is only about 24 nm.

In accordance with other embodiments, the results of the cross-sectional view of the evaporated high-density copper nano-twinned thin film on the (100) single-crystalline silicon substrate with simultaneous ion-beam bombardment show that the cross-sectional view contains the nano-scale parallel-arranged twin boundaries Σ3 and Σ9 which accounts for 48% and 7% of the total twin boundaries, respectively. In total, the nano-scale parallel-arranged twin boundaries (Σ3+Σ9) account for 55% of the total twin boundaries, and the parallel-arranged twin boundaries include 85% of the crystal orientation [111]. The evaporation parameters and ion gun parameters of the embodiment are described as follows.

Evaporation rate: titanium: 0.1 nm/s, copper: 0.35 nm/s; Thickness: 7 μm; Background pressure: less than 6×10⁻⁶ Torr; Flow rate of argon: 4.5 sccm; Working pressure of argon: 1.5×10⁻⁴ Torr; Rotation speed of stage: 10 rpm; Process temperature: normal temperature; Voltage of ion gun: 100V; and Current of ion gun: 0.4 A.

In accordance with other embodiments, the results of the cross-sectional view of the evaporated high-density gold nano-twinned thin film on the (100) single-crystalline silicon substrate with simultaneous ion-beam bombardment show that the cross-sectional view contains the nano-scale parallel-arranged twin boundaries Σ3 and Σ9 which accounts for 41% and 12% of the total twin boundaries, respectively. In total, the nano-scale parallel-arranged twin boundaries (Σ3+Σ9) account for 53% of the total twin boundaries, and the parallel-arranged twin boundaries include 73% of the crystal orientation [111]. The evaporation parameters and ion gun parameters of the embodiment are described as follows.

Evaporation rate: titanium: 0.1 nm/s, gold: 1.8 nm/s; Thickness: 7 μm; Background pressure: less than 6×10⁻⁶ Torr; Flow rate of argon: 4.5 sccm; Working pressure of argon: 1.5×10⁻⁴ Torr; Rotation speed of stage: 10 rpm; Process temperature: normal temperature; Voltage of ion gun: 100V; and Current of ion gun: 0.4 A.

In accordance with other embodiments, the results of the cross-sectional view of the evaporated high-density palladium nano-twinned thin film on the (100) single-crystalline silicon substrate with simultaneous ion-beam bombardment show that the cross-sectional view contains the nano-scale parallel-arranged twin boundaries Σ3 and Σ9 which accounts for 33% and 9% of the total twin boundaries, respectively. In total, the nano-scale parallel-arranged twin boundaries (Σ3+Σ9) account for 42% of the total twin boundaries, and the parallel-arranged twin boundaries include 64% of the crystal orientation [111]. The evaporation parameters and ion gun parameters of the embodiment are described as follows.

Evaporation rate: titanium: 0.1 nm/s, palladium: 1.8 nm/s; Thickness: 7 μm; Background pressure: less than 6×10⁻⁶ Torr; Flow rate of argon: 4.5 sccm; Working pressure of argon: 1.5×10⁻⁴ Torr; Rotation speed of stage: 10 rpm; Process temperature: normal temperature; Voltage of ion gun: 100V; and Current of ion gun: 0.4 A.

In accordance with other embodiments, the results of the cross-sectional view of the evaporated high-density nickel nano-twinned thin film on the (100) single-crystalline silicon substrate with simultaneous ion-beam bombardment show that the cross-sectional view contains the nano-scale parallel-arranged twin boundaries Σ3 and Σ9 which accounts for 31% and 11% of the total twin boundaries, respectively. In total, the nano-scale parallel-arranged twin boundaries (Σ3+Σ9) account for 42% of the total twin boundaries, and the parallel-arranged twin boundaries include 62% of the crystal orientation [111]. The evaporation parameters and ion gun parameters of the embodiment are described as follows.

Evaporation rate: titanium: 0.1 nm/s, nickel: 0.1 nm/s; Thickness: 7 μm; Background pressure: less than 6×10⁻⁶ Torr; Flow rate of argon: 4.5 sccm; Working pressure of argon: 1.5×10⁻⁴ Torr; Rotation speed of stage: 10 rpm; Process temperature: normal temperature; Voltage of ion gun: 100V; and Current of ion gun: 0.4 A.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A metallic nano-twinned thin film structure, comprising:
a substrate;
an adhesive-lattice-buffer layer over the substrate; and
a single-layer or multi-layer metallic nano-twinned thin film over the adhesive-lattice-buffer layer, wherein the metallic nano-twinned thin film comprises parallel-arranged twin boundaries (Σ3+Σ9), in a cross-sectional view of the metallic nano-twinned thin film, the parallel-arranged twin boundaries account for 30% to 90% of total twin boundaries, and the parallel-arranged twin boundaries comprise 80% to 99% of crystal orientation [111], wherein the single-layer metallic nano-twinned thin film comprises copper, gold, palladium or nickel, and the multi-layer metallic nano-twinned thin films are respectively composed of silver, copper, gold, palladium or nickel.

2. The metallic nano-twinned thin film structure as claimed in claim 1, wherein the metallic nano-twinned thin film comprises a plurality of nano-twinned pillars with a diameter of 0.01 μm to 10 μm.

3. The metallic nano-twinned thin film structure as claimed in claim 1, wherein a thickness of the metallic nano-twinned thin film is between 0.1 μm and 100 μm.

4. The metallic nano-twinned thin film structure as claimed in claim 1, wherein a thickness of the adhesive-lattice-buffer layer is between 0.01 μm and 1 μm.

5. The metallic nano-twinned thin film structure as claimed in claim 1, wherein a distance between the parallel-arranged twin boundaries is between 1 nm and 100 nm.

6. The metallic nano-twinned thin film structure as claimed in claim 1, further comprising a diffusion-barrier-reaction layer between the adhesion-lattice-buffer layer and the metallic nano-twinned thin film.

7. The metallic nano-twinned thin film structure as claimed in claim 1, wherein the adhesive-lattice-buffer layer comprises titanium, chromium, aluminum or a combination thereof.

8. The metallic nano-twinned thin film structure as claimed in claim 6, wherein the diffusion-barrier-reaction layer comprises nickel, copper or a combination thereof.

9. The metallic nano-twinned thin film structure as claimed in claim 1, wherein the substrate comprises a silicon substrate, a silicon carbide substrate, a gallium arsenide substrate, a sapphire substrate or a glass substrate.

10. A method for forming a metallic nano-twinned thin film structure, comprising:
forming an adhesive-lattice-buffer layer on a substrate; and
forming a single-layer or multi-layer metallic nano-twinned thin film on the adhesive-lattice-buffer layer, wherein the metallic nano-twinned thin film comprises parallel-arranged twin boundaries (Σ3+Σ9), in a cross-sectional view of the metallic nano-twinned thin film, the parallel-arranged twin boundaries account for 30% to 90% of total twin boundaries, and the parallel-arranged twin boundaries comprise 80% to 99% of crystal orientation [111], wherein the single-layer metallic nano-twinned thin film comprises copper, gold, palladium or nickel, and the multi-layer metallic nano-twinned thin films are respectively composed of silver, copper, gold, palladium or nickel.

11. The method as claimed in claim 10, wherein the adhesive-lattice-buffer layer is formed by sputtering or evaporation.

12. The method as claimed in claim 10, wherein the metallic nano-twinned thin film is formed on the adhesive-lattice-buffer layer by ion-beam bombardment-assisted evaporation.

13. The method as claimed in claim 10, further comprising forming a diffusion-barrier-reaction layer between the adhesive-lattice-buffer layer and the metallic nano-twinned thin film by evaporation, sputtering or electroplating.

14. The method as claimed in claim 13, wherein the metallic nano-twinned thin film is formed on the diffusion-barrier-reaction layer by ion-beam bombardment-assisted evaporation.

15. The method as claimed in claim 10, wherein the substrate comprises a silicon substrate, a silicon carbide substrate, a gallium arsenide substrate, a sapphire substrate or a glass substrate.
